(19) United States
(12) Patent Application Publication
(10) Pub. No.: US 2025/0133916 A1
(43) Pub. Date: Apr. 24, 2025

(54) DISPLAY DEVICE AND MOTHER SUBSTRATE FOR DISPLAY DEVICE

(71) Applicant: Japan Display Inc., Tokyo (JP)

(72) Inventors: Naoya IWAHASHI, Tokyo (JP); Sho YANAGISAWA, Tokyo (JP); Hideyuki TAKAHASHI, Tokyo (JP)

(73) Assignee: Japan Display Inc., Tokyo (JP)

(21) Appl. No.: 18/915,402

(22) Filed: Oct. 15, 2024

(30) Foreign Application Priority Data
Oct. 18, 2023 (JP) 2023-179399

(51) Int. Cl. H10K 59/122

(52) U.S. Cl. CPC H10K 59/122

(57) ABSTRACT

According to one embodiment, a display device includes a substrate having display and surrounding areas, an organic insulating layer, a lower electrode above the organic insulating layer, a rib layer having a pixel aperture, a first partition in the display area, an organic layer contacting the lower electrode, an upper electrode covering the organic layer, and a second partition in the surrounding area. Each of the first and second partitions includes a lower portion and an upper portion having an end portion which protrudes from a side surface of the lower portion. The second partition includes segments spaced apart from each other. The rib layer has a slit surrounding at least one of the segments.

### CROSS-REFERENCE TO RELATED APPLICATION

This application is based upon and claims the benefit of priority from Japanese Patent Application No. 2023-179399, filed Oct. 18, 2023, the entire contents of which are incorporated herein by reference.

### FIELD

Embodiments described herein relate generally to a display device and a mother substrate for a display device.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is the schematic cross-sectional view of a display panel along the III-III line of FIG. 2.

FIG. 4 is a schematic plan view of a mother substrate according to the first embodiment.

FIG. 5 is a schematic plan view of part of the mother substrate according to the first embodiment.

FIG. 6 is a schematic plan view showing an example of a partition provided in a margin area, a surrounding area and an inspection area.

FIG. 7 is the schematic cross-sectional view of the mother substrate along the VII-VII line of

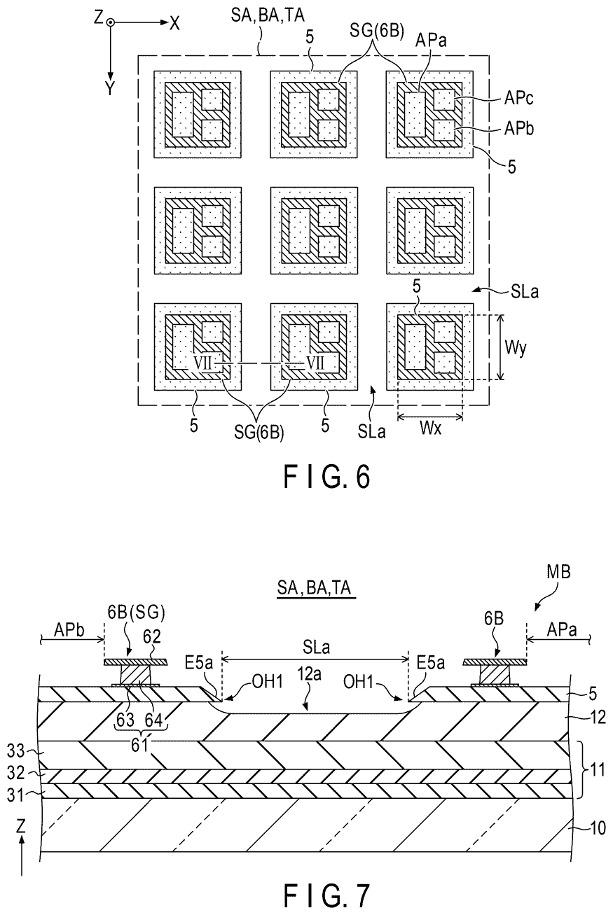

FIG. 6.

FIG. 8 is a schematic plan view of a cut line between the margin area and the inspection area and the vicinity of the cut line.

FIG. 9 is the schematic cross-sectional view of the mother substrate along the IX-IX line of FIG. 8.

FIG. 10 is the schematic cross-sectional view of the mother substrate along the X-X line of FIG. 8.

FIG. 11A is a schematic cross-sectional view showing the process of forming panel portions in the mother substrate.

FIG. 11B is a schematic cross-sectional view showing a process following FIG. 11A.

FIG. 11C is a schematic cross-sectional view showing a process following FIG. 11B.

FIG. 11D is a schematic cross-sectional view showing a process following FIG. 11C.

FIG. 11E is a schematic cross-sectional view showing a process following FIG. 11D.

FIG. 11F is a schematic cross-sectional view showing a process following FIG. 11E.

FIG. 11G is a schematic cross-sectional view showing a process following FIG. 11F.

FIG. 11H is a schematic cross-sectional view showing a process following FIG. 11G.

FIG. 11I is a schematic cross-sectional view showing a process following FIG. 11H.

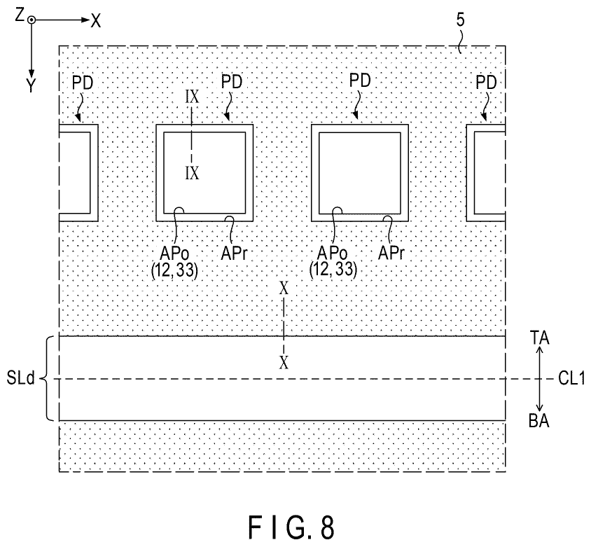

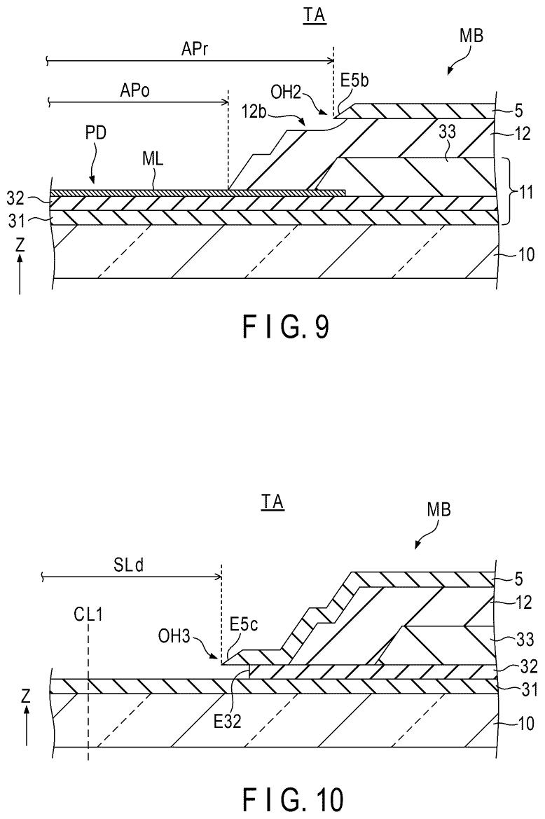

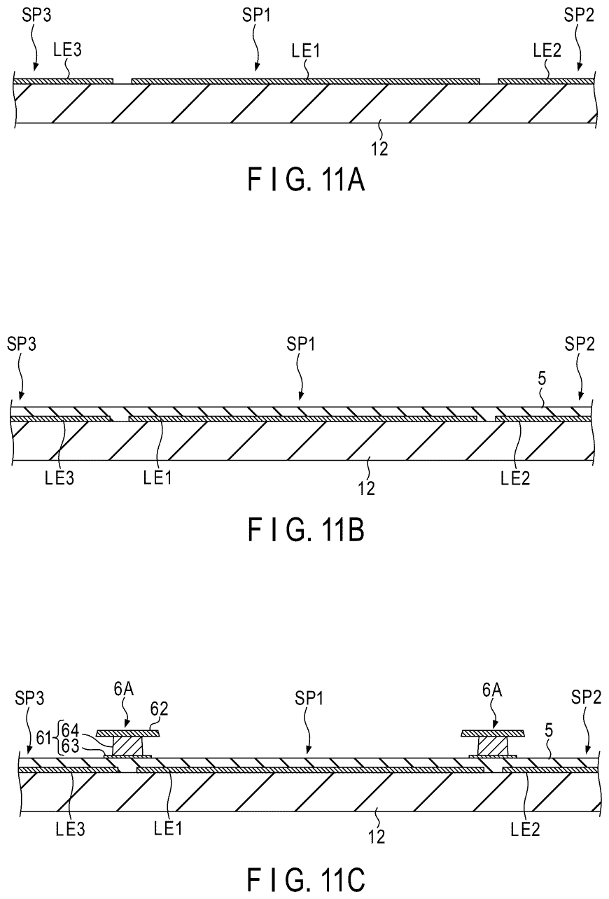

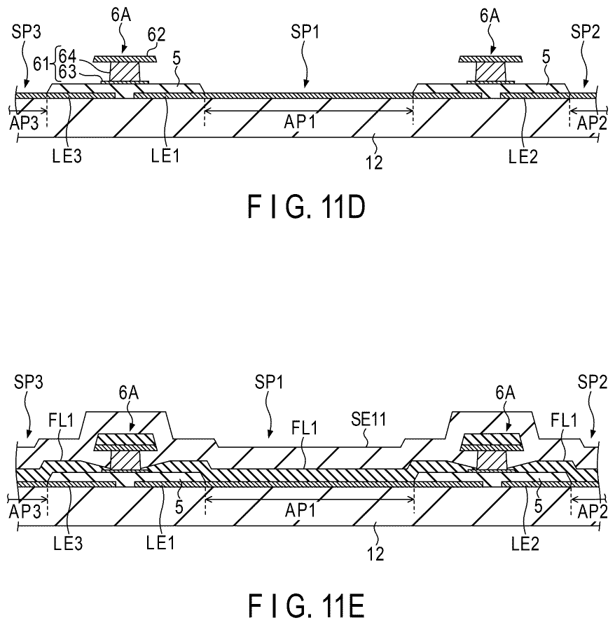

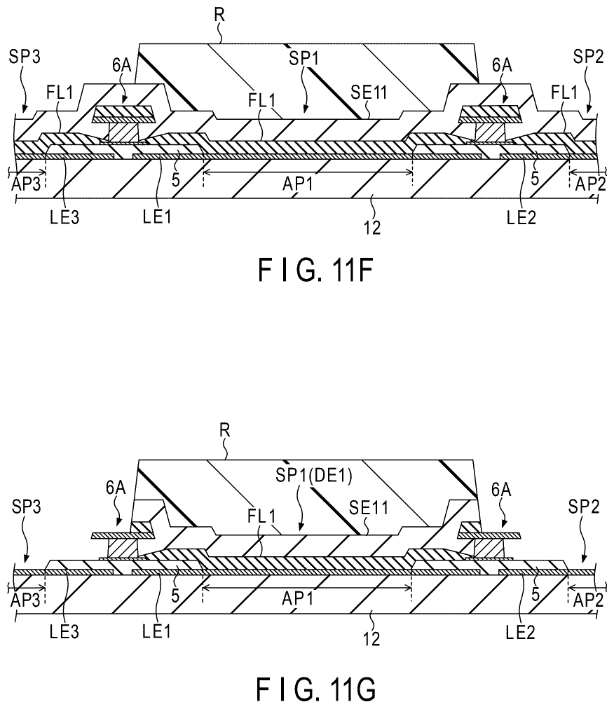

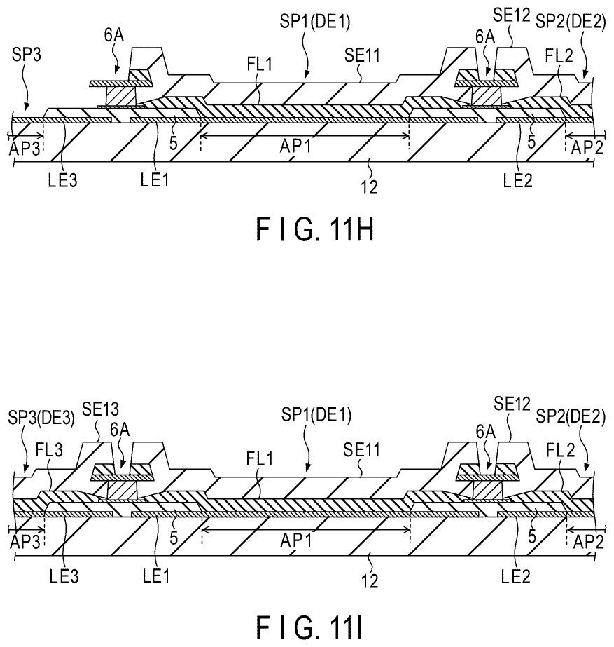

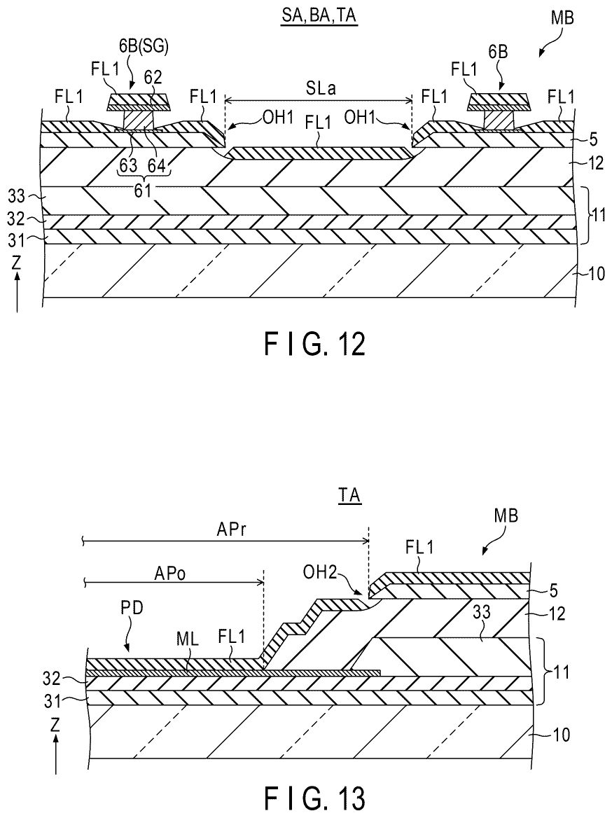

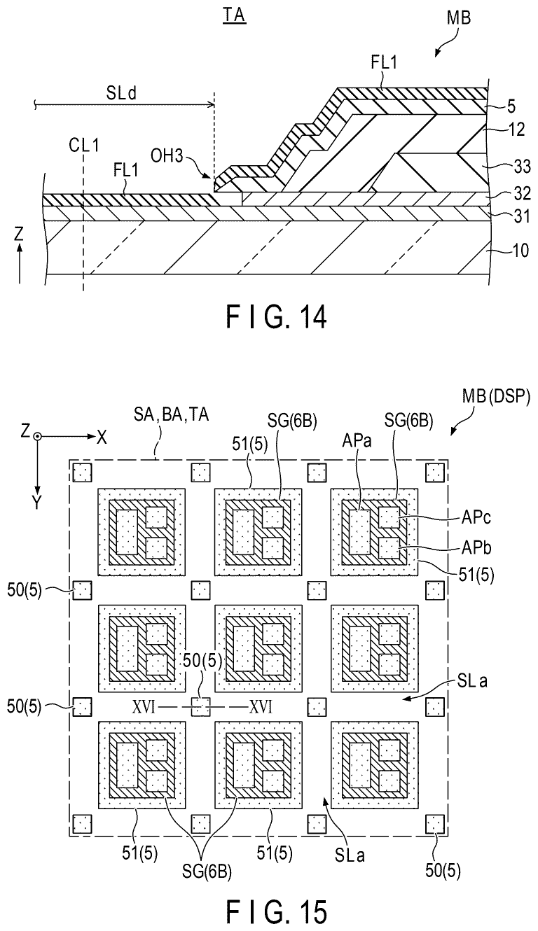

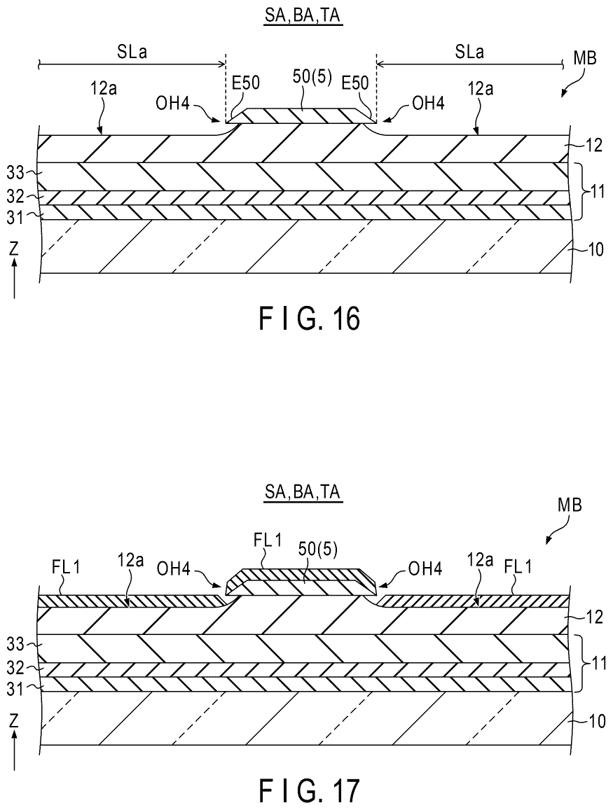

FIG. 12 is a schematic cross-sectional view showing the effect of the overhang structure shown in FIG. 7.

FIG. 13 is a schematic cross-sectional view showing the effect of the overhang structure shown in FIG. 9.

FIG. 14 is a schematic cross-sectional view showing the effect of the overhang structure shown in FIG. 10.

FIG. 15 is a schematic plan view showing the configuration of a mother substrate or a display device according to a second embodiment.

FIG. 16 is the schematic cross-sectional view of the mother substrate along the XVI-XVI line of FIG. 15.

FIG. 17 is a schematic cross-sectional view showing the effect of the second embodiment.

### DETAILED DESCRIPTION

In general, according to an embodiment, a display device comprises a substrate having a display area which displays an image and a surrounding area around the display area, an organic insulating layer formed of an organic insulating material and provided above the substrate, a lower electrode provided above the organic insulating layer in the display area, a rib layer which is formed of an inorganic insulating material, covers the organic insulating layer and the lower electrode and has a pixel aperture overlapping the lower electrode, a first partition provided above the rib layer in the display area, an organic layer which is in contact with the lower electrode through the pixel aperture and emits light based on application of voltage, an upper electrode which covers the organic layer and is in contact with the first partition, and a second partition provided above the rib layer in the surrounding area. Each of the first partition and the second partition includes a lower portion provided above the rib layer and an upper portion having an end portion which protrudes from a side surface of the lower portion. The second partition includes a plurality of segments which are spaced apart from each other. Further, the rib layer has a slit which surrounds at least one of the segments.

According to another aspect of the embodiment, a display device comprises a substrate having a display area which displays an image and a surrounding area around the display area, an inorganic insulating layer formed of an inorganic insulating material and provided above the substrate, an organic insulating layer formed of an organic insulating material and provided above the inorganic insulating layer, a lower electrode provided above the organic insulating layer in the display area, a rib layer which is formed of an inorganic insulating material, covers the organic insulating layer and the lower electrode and has a pixel aperture overlapping the lower electrode, an organic layer which is in contact with the lower electrode through the pixel aperture and emits light based on application of voltage, and an upper electrode which covers the organic layer. Further, an overhang structure in which an edge portion of the rib layer protrudes from an edge portion of the inorganic insulating layer is formed in the surrounding area.

In general, according to an embodiment, a mother substrate for a display device comprises a substrate which has a plurality of panel portions each including a display area and a surrounding area around the display area, and a margin area around the panel portions, an organic insulating layer formed of an organic insulating material and provided above the substrate, a lower electrode provided above the organic insulating layer in the display area, a rib layer which is formed of an inorganic insulating material, covers the organic insulating layer and the lower electrode and has a pixel aperture which overlaps the lower electrode, a first partition provided above the rib layer in the display area, an organic layer which is in contact with the lower electrode through the pixel aperture and emits light based on application of voltage, an upper electrode which covers the organic layer and is in contact with the first partition, and a second partition provided above the rib layer in at least one of the surrounding area and the margin area. Each of the first partition and the second partition includes a lower portion provided above the rib layer and an upper portion having an end portion protruding from a side surface of the lower portion. The second partition includes a plurality of segments which are spaced apart from each other. Further, the rib layer has a slit which surrounds at least one of the segments.

According to another aspect of the embodiment, a mother substrate for a display device comprises a substrate which has a plurality of panel portions each including a display area and a surrounding area around the display area, and a margin area around the panel portions, an inorganic insulating layer provided above the substrate, an organic insulating layer formed of an organic insulating material and provided above the inorganic insulating layer, a lower electrode provided above the organic insulating layer in the display area, a rib layer which is formed of an inorganic insulating material, covers the organic insulating layer and the lower electrode and has a pixel aperture which overlaps the lower electrode, an organic layer which is in contact with the lower electrode through the pixel aperture and emits light based on application of voltage, and an upper electrode which covers the organic layer. Further, an overhang structure in which an edge portion of the rib layer protrudes from an end portion of the inorganic insulating layer is formed in at least one of the surrounding area and the margin area.

According to yet another aspect of the embodiment, a mother substrate for a display device comprises a substrate which has a plurality of panel portions each including a display area and a surrounding area around the display area, and a margin area around the panel portions, an organic insulating layer formed of an organic insulating material and provided above the substrate, a lower electrode provided above the organic insulating layer in the display area, a rib layer which is formed of an inorganic insulating material, covers the organic insulating layer and the lower electrode and has a pixel aperture which overlaps the lower electrode, an organic layer which is in contact with the lower electrode through the pixel aperture and emits light based on application of voltage, and an upper electrode which covers the organic layer. Further, the rib layer has a first slit which surrounds the display area in at least one of the panel portions.

Each of the configurations described above can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

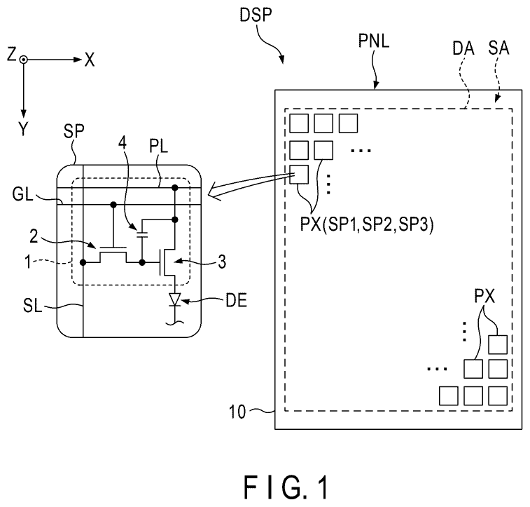

FIG. 1 is a diagram showing a configuration example of a display device DSP according to a first embodiment. The display device DSP comprises a display panel PNL including an insulating substrate 10. The display panel PNL has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply scanning signals to the pixel circuits 1 of subpixels SP, a plurality of signal lines SL which supply video signals to the pixel circuits 1 of subpixels SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. One of the source electrode and drain electrode of the pixel switch 2 is connected to the signal line SL. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

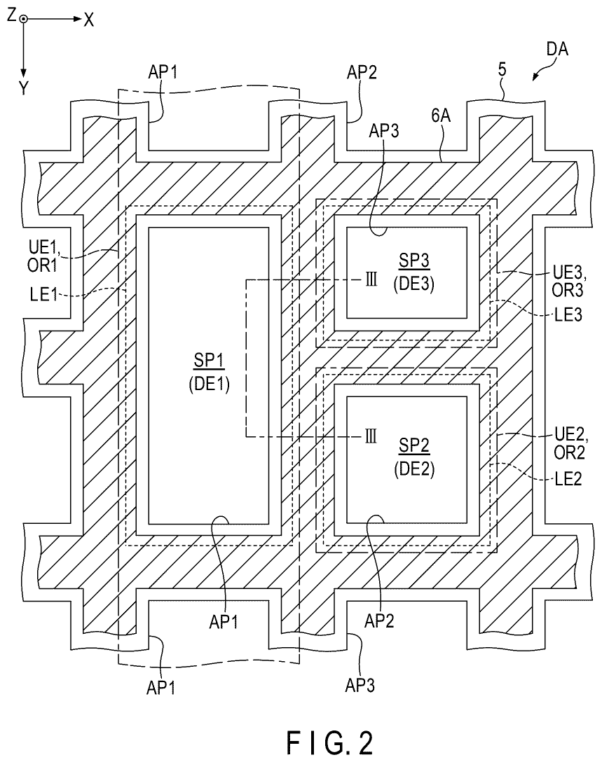

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition (first partition) 6A is provided above the rib layer 5. The partition 6A overlaps the rib layer 5 as a whole and has a planar shape similar to that of the rib layer 5. In other words, the partition 6A has an aperture in each of subpixels SP1, SP2 and SP3. From another viewpoint, the rib layer 5 and the partition 6A have grating shapes as seen in plan view and surround each of the display elements DE1, DE2 and DE3. The partition 6A functions as lines which apply common voltage to the upper electrodes UE1, UE2 and UE3.

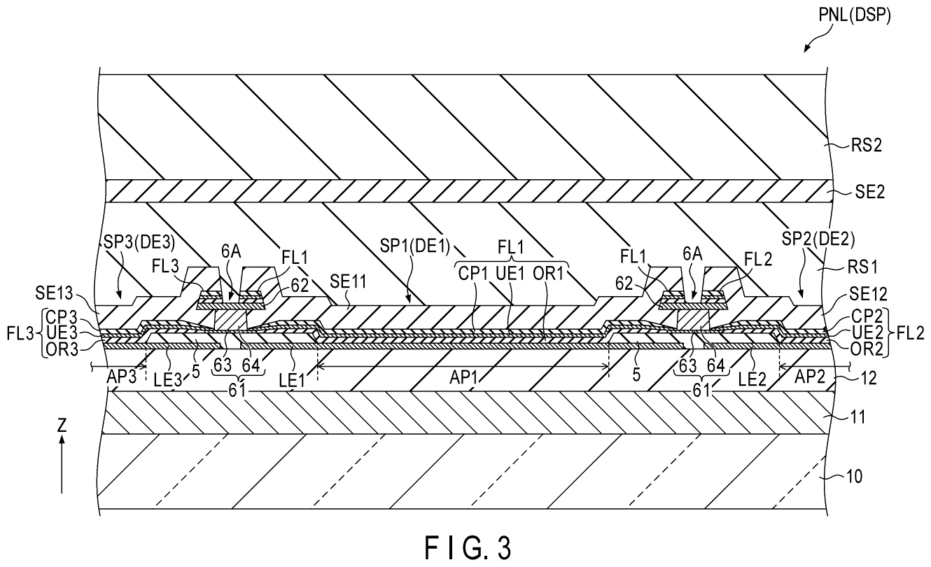

FIG. 3 is the schematic cross-sectional view of the display panel PNL along the III-III line of FIG. 2. A circuit layer 11 is provided on the substrate 10 described above. The circuit layer 11 includes various circuits and lines such as the pixel circuits 1, scanning lines GL, signal lines SL and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12. The partition 6A includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6A is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6A.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6A (in other words, the portion which constitutes the display element DE1). Similarly, the stacked film FL2 is partly located on the upper portion 62. This portion is spaced apart from, of the stacked film FL2, the portion located around the partition 6A (in other words, the portion which constitutes the display element DE2). Further, the stacked film FL3 is partly located on the upper portion 62. This portion is spaced apart from, of the stacked film FL3, the portion located around the partition 6A (in other words, the portion which constitutes the display element DE3).

Sealing layers SE11, SE12 and SE13 are provided in subpixels SP1, SP2 and SP3, respectively. The sealing layer SE11 continuously covers the cap layer CP1 and the partition 6A around subpixel SP1. The sealing layer SE12 continuously covers the cap layer CP2 and the partition 6A around subpixel SP2. The sealing layer SE13 continuously covers the cap layer CP3 and the partition 6A around subpixel SP3.

In the example of FIG. 3, the stacked film FL1 and sealing layer SE11 located on the partition 6A between subpixels SP1 and SP2 are spaced apart from the stacked film FL2 and sealing layer SE12 located on this partition 6A. The stacked film FL1 and sealing layer SE11 located on the partition 6A between subpixels SP1 and SP3 are spaced apart from the stacked film FL3 and sealing layer SE13 located on this partition 6A.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6A is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6A comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6A. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage.

Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

When the display device DSP is manufactured, a large mother substrate in which a plurality of areas (panel portions) each corresponding to the display panel PNL are formed is prepared. A configuration which could be applied to this mother substrate is explained below.

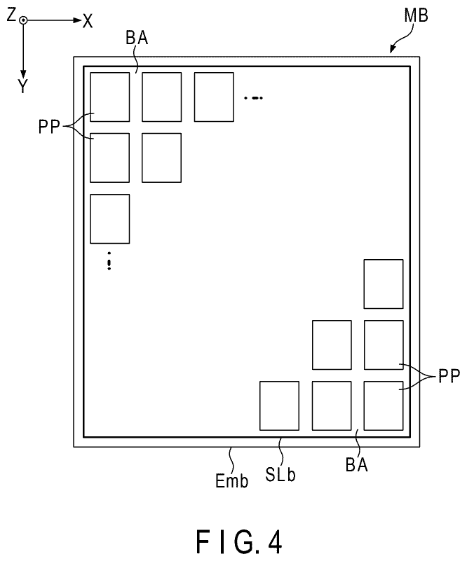

FIG. 4 is a schematic plan view of a mother substrate MB (a mother substrate for a display device) according to the embodiment. The mother substrate MB is, for example, rectangular as shown in the figure. However, the mother substrate MB may have another shape such as a circle. The mother substrate MB comprises a plurality of panel portions PP provided in matrix, and a margin area BA around these panel portions PP.

In the example of FIG. 4, the margin area BA is provided both between the panel portions PP which are adjacent to each other in the X-direction and between the panel portions PP which are adjacent to each other in the Y-direction. As another example, the panel portions PP which are arranged in the X-direction may be adjacent to each other without intervention of the margin area BA. Alternatively, the panel portions PP which are arranged in the Y-direction may be adjacent to each other without intervention of the margin area BA.

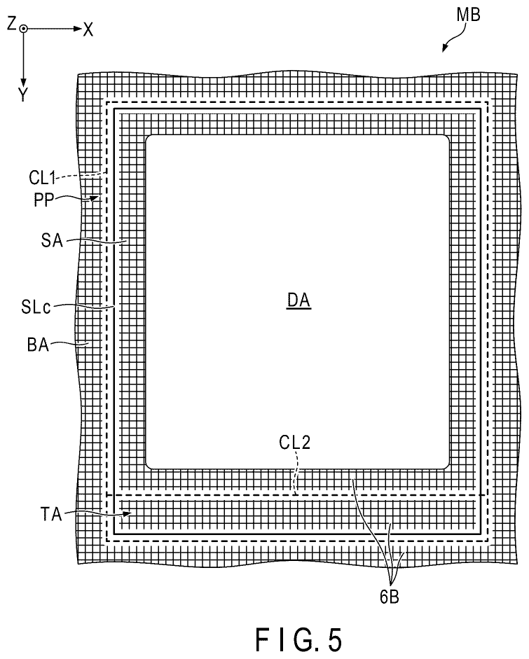

FIG. 5 is a schematic plan view of part of the mother substrate MB. The outer shape of each panel portion PP corresponds to a cut line CL1 for cutting the panel portion PP from the mother substrate MB.

Each panel portion PP has the display area DA and surrounding area SA described above. Further, each panel portion PP has an inspection area TA. In the inspection area TA, inspection pads (see FIG. 8) for inspecting the operation of the display panel PNL are provided.

A cut line CL2 is formed between the surrounding area SA and the inspection area TA. When the display device DSP is manufactured, first, the panel portion PP is cut from the mother substrate MB along the cut line CL1. Further, the above inspection is performed for the cut panel portion PP. After this inspection, the inspection area TA is separated from the panel portion PP along the cut line CL2.

In this embodiment, a partition (second partition) 6B is provided in the margin area BA, the surrounding area SA and the inspection area TA. In FIG. 5, a grating pattern is added to the area in which the partition 6B could be provided. It should be noted that this grating pattern does not show the actual shape of the partition 6B.

To effectively cut out the panel portion PP, it is preferable that the partition 6B should not be provided in the cut line CL1. Similarly, it is preferable that the partition 6B should not be provided in the cut line CL2.

FIG. 6 is a schematic plan view showing an example of the partition 6B provided in the margin area BA, the surrounding area SA and the inspection area TA. The partition 6B has a plurality of segments SG spaced apart from each other. In the example of FIG. 6, these segments SG have the same shape and are arranged in the X-direction and the Y-direction. Each segment SG is a quadrangle (a rectangle or a square) which has two sides extending in the X-direction and two sides extending in the Y-direction.

Each segment SG has three apertures APa, APb and APC. The apertures APa, APb and APc are provided in line with, for example, a layout similar to that of the pixel apertures AP1, AP2 and AP3. Specifically, in the example of FIG. 6, each of the apertures APb and APc is adjacent to the aperture APa in the X-direction. Further, the apertures APb and APc are arranged in the Y-direction. The apertures APb and APc are smaller than the aperture APa. The sizes of the apertures APb and APc are, for example, equal to each other. However, they may be different from each other.

Each segment SG has width Wx in the X-direction and has width Wy in the Y-direction. Widths Wx and Wy are, for example, greater than or equal to the width of each pixel PX in the X-direction and the width of each pixel PX in the Y-direction, respectively. However, width Wx or Wy is not limited to this example. Widths Wx and Wy may be equal to each other or may be different from each other.

It should be noted that the segments SG having the shapes shown in FIG. 6 are not necessarily provided in the entire part of the margin area BA, the surrounding area SA and the inspection area TA. A segment (partition 6B) having another shape may be provided in at least part of the margin area BA, the surrounding area SA and the inspection area TA.

In addition, the shape of each segment SG is not limited to the quadrangle shown in FIG. 6. The shape of each segment SG may be another polygonal shape or may be a shape including a curved outline. Further, the number of apertures provided in each segment SG or the shape of each aperture is not limited to the example of FIG. 6.

The dotted areas of FIG. 6 correspond to the rib layer 5. The rib layer 5 is formed in the margin area BA, the surrounding area SA and the inspection area TA as well as the display area DA. Each segment SG is provided on the rib layer 5.

The rib layer 5 has a slit SLa located between the adjacent segments SG. In the example of FIG. 6, the slit SLa has a grating shape which includes portions extending in the X-direction and portions extending in the Y-direction. The slit SLa surrounds each of the segments SG. It should be noted that part of the segments SG may not be surrounded by the slit SLa.

In addition, the rib layer 5 has the slit SLb shown in FIG. 4 and the slit SLc shown in FIG. 5. The slit SLb is provided along the edge portion Emb of the mother substrate MB and surrounds the panel portions PP. The slit SLc is provided along the cut line CL1 of the panel portion PP and surrounds at least the display area DA. In the example of FIG. 5, the slit SLC further surrounds a large part of the surrounding area SA and the inspection area TA.

FIG. 7 is the schematic cross-sectional view of the mother substrate MB along the VII-VII line of FIG. 6. The circuit layer 11 shown in FIG. 3 includes a plurality of metal layers and semiconductor layers, and a plurality of insulating layers provided between the metal layers and the semiconductor layers. FIG. 7 shows inorganic insulating layers 31 and 32 and an organic insulating layer 33 stacked in order in the Z-direction as examples of the insulating layers provided in the circuit layer 11.

Each of the inorganic insulating layers 31 and 32 can be formed of, for example, an inorganic insulating material such as silicon nitride, silicon oxide or silicon oxynitride. For example, the inorganic insulating layer 31 is formed of silicon nitride or silicon oxide, and the inorganic insulating layer 32 is formed of silicon nitride. The organic insulating layer 33 is formed of an organic insulating material such as polyimide in a manner similar to that of the organic insulating layer 12.

The partition 6B is provided on the rib layer 5 in a manner similar to that of the partition 6A. In the example of FIG. 7, the inorganic insulating layers 31 and 32 and the organic insulating layers 12 and 33 are provided under the partition 6B. It should be noted that at least one of the inorganic insulating layers 31 and 32 and the organic insulating layers 12 and 33 may not be provided under the partition 6B in at least part of the margin area BA, the surrounding area SA and the inspection area TA.

The partition 6B includes a lower portion 61 and an upper portion 62 in a manner similar to that of the partition 6A. Further, the lower portion 61 of the partition 6B includes a bottom layer 63 and a stem layer 64. In the partition 6B, similarly, the end portions of the upper portion 62 protrude from the side surfaces of the lower portion 61 (stem layer 64).

No aperture is provided in the rib layer 5 in the aperture APa, APb or APc. In the slit SLa, the organic insulating layer 12 is exposed from the rib layer 5.

The organic insulating layer 12 has a groove 12a (recess portion) which overlaps the slit SLa. The planar shape of the groove 12a is similar to that of the slit SLa shown in FIG. 6.

For example, the edge portion E5a of the rib layer 5 along the slit SLa has a taper shape in which the thickness decreases toward the distal end. In the example of FIG. 7, the edge portion E5a protrudes above the groove 12a. In other words, an overhang structure OH1 along the slit SLa is formed by the edge portion E5a and the groove 12a.

The cross-sectional structures of the slit SLb shown in FIG. 4 and the slit SLc shown in FIG. 5 are similar to the cross-sectional structure of the slit SLa shown in FIG. 7. Specifically, the organic insulating layer 12 has a groove 12a which overlaps each of the slits SLb and SLc, and the edge portion E5a of the rib layer 5 along each of the slits SLb and SLc protrudes above the groove 12a. Thus, an overhang structure OH1 along each of the slits SLb and SLc is formed.

The overhang structure OH1 along each of the slits SLa and SLc remains in the panel portion PP cut out of the mother substrate MB, and the display panel PNL which is obtained after cutting the inspection area TA of the panel portion PP along the cut line CL2.

FIG. 8 is a schematic plan view of the cut line CL1 between the margin area BA and the inspection area TA and the vicinity of the cut line CL1. The dotted areas correspond to the rib layer 5.

A plurality of inspection pads PD used for the inspection described above are provided in the inspection area TA. The rib layer 5 has apertures APr which overlap the inspection pads PD. The organic insulating layers 12 and 33 have apertures APo which overlap the apertures APr.

Further, the rib layer 5 has a slit SLd along the cut line CL1. Although the illustration is omitted in FIG. 8, the slit SLc shown in FIG. 5 may be located between the inspection pads PD and the cut line CL1 or may be located above the inspection pads PD in FIG. 8 (between the inspection pads PD and the display area DA).

FIG. 9 is the schematic cross-sectional view of the mother substrate MB along the IX-IX line of FIG. 8. The circuit layer 11 has a metal layer ML in addition to the inorganic insulating layers 31 and 32 and the organic insulating layer 33. The metal layer ML is provided on the inorganic insulating layer 32 and constitutes the inspection pad PD.

The metal layer ML is exposed through the aperture APo of the organic insulating layers 12 and 33 and the aperture APr of the rib layer 5. In the example of FIG. 9, the edge portion of the organic insulating layer 33 located near the aperture APo is covered with the organic insulating layer 12. As another example, the edge portion of the organic insulating layer 33 may be exposed from the organic insulating layer 12.

The edge portion E5b of the rib layer 5 along the aperture APr has a taper shape in which the thickness decreases toward the distal end, and is located above the organic insulating layer 12. The organic insulating layer 12 has a recess portion 12b which overlaps the aperture APr. The edge portion E5b protrudes above the recess portion 12b. In other words, an overhang structure OH2 along the aperture APr is formed by the edge portion E5b and the recess portion 12b.

FIG. 10 is the schematic cross-sectional view of the mother substrate MB along the X-X line of FIG. 8. The organic insulating layer 12 or 33 is provided near the cut line CL1. The rib layer 5 is in contact with the inorganic insulating layer 32 near the slit SLd.

The edge portion E5c of the rib layer 5 along the slit SLd has a taper shape in which the thickness decreases toward the distal end. In the example of FIG. 10, the inorganic insulating layer 32 is not provided in the slit SLd. The edge portion E5c of the rib layer 5 protrudes from the edge portion E32 of the inorganic insulating layer 32 along the slit SLd. In other words, an overhang structure OH3 along the slit SLd is formed by the edge portion E5c and the inorganic insulating layer 32.

In the mother substrate MB, the overhang structure OH3 is formed along the outer shape (cut line CL1) of each panel portion PP. The overhang structure OH3 remains in the panel portion PP cut out of the mother substrate MB, and the display panel PNL which is obtained after cutting the inspection area TA of the panel portion PP along the cut line CL2. Specifically, in the display panel PNL, the overhang structure OH3 is formed along the edge portion of the substrate 10 corresponding to the cut line CL1 shown in FIG. 5.

The inorganic insulating layer 32 is not necessarily entirely eliminated in the slit SLd. For example, in the inorganic insulating layer 32, the thickness of the portion which overlaps the slit SLd may be reduced compared to the other portion. Even in this case, the overhang structure OH3 can be formed when the edge portion E5c protrudes above the inorganic insulating layer 32 having the reduced thickness. In the example of FIG. 10, the inorganic insulating layer 31 is formed in the slit SLd. As another example, the inorganic insulating layer 31 may be eliminated in the slit SLd. Alternatively, the thickness of the inorganic insulating layer 31 may be reduced in the slit SLd.

Now, this specification explains an example of the manufacturing method of the display device DSP. FIG. 11A to FIG. 11I are schematic cross-sectional views showing the process of forming the panel portions PP in the mother substrate MB. In FIG. 11A to FIG. 11I, the display area DA is mainly looked at, and the elements located under the organic insulating layer 12 are omitted.

To form the panel portions PP, first, the circuit layer 11 and the organic insulating layer 12 are formed on the substrate 10 of the mother substrate MB. Subsequently, as shown in FIG. 11A, the lower electrodes LE1, LE2 and LE3 are formed on the organic insulating layer 12.

Subsequently, as shown in FIG. 11B, the rib layer 5 which covers the organic insulating layer 12 and the lower electrodes LE1, LE2 and LE3 is formed in the entire mother substrate MB. For example, chemical vapor deposition (CVD) can be used for the formation of the rib layer 5.

Further, as shown in FIG. 11C, the partition 6A is formed on the rib layer 5. Specifically, first, the base layers of the bottom layer 63, the stem layer 64 and the upper portion 62 are formed, and these layers are patterned by etching. The partition 6B shown in FIG. 7 is formed in the same process as the partition 6A.

After the formation of the partitions 6A and 6B, as shown in FIG. 11D, the pixel apertures AP1, AP2 and AP3 are formed in the rib layer 5 by dry etching. In addition to this process, a plurality of dry etching processes are performed for the rib layer 5. For example, these dry etching processes include etching for forming, in the rib layer 5, contact holes for connecting the partition 6A to the feed lines of the same layer as the lower electrodes LE1, LE2 and LE3 in the surrounding area SA, and etching for forming the apertures APr shown in FIG. 8. The slits SLa, SLb, SLC and SLd of the rib layer 5 can be formed in one of these etching processes.

After the formation of the rib layer 5 and the partitions 6A and 6B, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 11E, the stacked film FL1 and the sealing layer SE11 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE11 is formed by CVD.

The stacked film FL1 and the sealing layer SE11 are formed in the entire mother substrate MB including the surrounding area SA, the inspection area TA and the margin area BA as well as the display area DA of each panel portion PP. The stacked film FL1 is divided into a plurality of portions by the partitions 6A and 6B having overhang shapes. The sealing layer SE11 continuously covers the portions into which the stacked film FL1 is divided, and the partitions 6A and 6B.

Subsequently, the stacked film FL1 and the sealing layer SE11 are patterned. In this patterning, as shown in FIG. 11F, a resist R is provided on the sealing layer SE11. The resist R covers subpixel SP1 and part of the partition 6A around the subpixel.

Subsequently, as shown in FIG. 11G, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. For example, in the surrounding area SA, the inspection area TA and the margin area BA, the stacked film FL1 and the sealing layer SE11 are removed by this etching. This etching could include wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire mother substrate MB. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partitions 6A and 6B having overhang shapes. The sealing layer SE12 continuously covers the portions into which the stacked film FL2 is divided, and the partitions 6A and 6B. By patterning these stacked film FL2 and sealing layer SE2, the display element DE2 is formed in subpixel SP2 as shown in FIG. 11H. For example, in the surrounding area SA, the inspection area TA and the margin area BA, the stacked film FL2 and the sealing layer SE12 are removed by etching at the time of this patterning.

The display element DE3 is formed by a procedure similar to the procedures of the display elements DE1 and DE2. Specifically, when the display element DE3 is formed, the stacked film FL3 and the sealing layer SE13 are formed in the entire mother substrate MB. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partitions 6A and 6B having overhang shapes. The sealing layer SE13 continuously covers the portions into which the stacked film FL3 is divided, and the partitions 6A and 6B. By patterning these stacked film FL3 and sealing layer SE13, the display element DE3 is formed in subpixel SP3 as shown in FIG. 11I. For example, in the surrounding area SA, the inspection area TA and the margin area BA, the stacked film FL3 and the sealing layer SE13 are removed by etching at the time of this patterning.

After the display elements DE1, DE2 and DE3 are formed, the resin layer RS1, sealing layer SE2 and resin layer RS2 shown in FIG. 3 are formed in order. Further, each panel portion PP is cut out of the mother substrate MB along the cut lines CL1.

Subsequently, inspection is performed for each panel portion PP. This inspection includes, for example, the lighting inspection of each of the display elements DE1, DE2 and DE3 using the inspection pads provided in the inspection area TA. After the inspection, the inspection area TA is cut along the cut line CL2. In this manner, the display panel PNL is completed.

It should be noted that at least one of the stacked films FL1, FL2 and FL3 may be left without being removed in the surrounding area SA, the inspection area TA and the margin area BA.

As described above, a plurality of dry etching processes are performed for the rib layer 5. The overhang structures OH1, OH2 and OH3 shown in FIG. 7, FIG. 9 and FIG. 10, respectively, are formed in, for example, one of these dry etching processes.

In other words, in the dry etching for forming the slit SLa shown in FIG. 7, the organic insulating layer 12 located under the rib layer 5 is also corroded through the slit SLa, and the groove 12a is formed in the organic insulating layer 12. In this manner, the overhang structure OH1 is formed. Regarding the slits SLb and SLc shown in FIG. 4 and FIG. 5, similarly, the organic insulating layer 12 is corroded by dry etching for forming the slits SLb and SLc, and the overhang structure OH1 is formed.

In the dry etching for forming the aperture APr shown in FIG. 9, the organic insulating layer 12 located under the rib layer 5 is also corroded through the aperture APr, and the recess portion 12b is formed in the organic insulating layer 12. In this manner, the overhang structure OH2 is formed.

Further, in the dry etching for forming the slit SLd shown in FIG. 10, the inorganic insulating layer 32 located under the rib layer 5 is also corroded through the slit SLd. In this manner, the overhang structure OH3 is formed. To form the overhang structure OH3 having a satisfactory shape, the rib layer 5 and the inorganic insulating layer 32 should be preferably formed of different inorganic insulating materials such that the etching rate of the inorganic insulating layer 32 in this dry etching is faster than that of the rib layer 5. For example, when the inorganic insulating layer 32 is formed of silicon nitride, and the rib layer 5 is formed of silicon oxynitride, this difference in the etching rate could be realized.

It should be noted that each of the overhang structures OH1, OH2 and OH3 may be formed by a combination of dry etching for processing the rib layer 5 and another dry etching process. In other words, the groove 12a of the overhang structure OH1 may be formed by another etching process which is performed after the formation of the slits SLa, SLb and SLc in the rib layer 5. The recess portion 12b of the overhang structure OH2 may be formed by another etching process which is performed after the formation of the apertures APr in the rib layer 5. Further, the overhang structure OH3 may be formed as the inorganic insulating layer 32 is corroded by another etching process which is performed after the formation of the slit SLd in the rib layer 5.

Now, this specification explains several effects obtained from the embodiment. When the display elements DE1, DE2 and DE3 are formed, the stacked films FL1, FL2 and FL3 are formed in the entire mother substrate MB. The stacked films FL1, FL2 and FL3 which are formed by vapor deposition have weak adherence to the base. Therefore, there is a possibility that the stacked films FL1, FL2 and FL3 are peeled from the base during the manufacturing process of the display device DSP. When this peeling expands, the stacked films FL1, FL2 and FL3 and the sealing layers SE11, SE12 and SE13 located on these stacked films may be removed. Thus, they could be undesired particles.

In the display area DA, the stacked films FL1, FL2 and FL3 are divided into pieces by the partition 6A having a grating shape. Therefore, the stacked film FL1, FL2 or FL3 is not easily removed from the base. In addition, in this embodiment, the removal of the stacked films FL1, FL2 and FL3 can be prevented in the surrounding area SA, the inspection area TA and the margin area BA by the partition 6B and the overhang structures OH1, OH2 and OH3.

FIG. 12, FIG. 13 and FIG. 14 are schematic cross-sectional views showing the effects of the overhang structures OH1, OH2 and OH3, respectively. These cross-sectional views correspond to the state in which the stacked film FL1 is formed in portions similar to those of FIG. 7, FIG. 9 and FIG. 10, respectively.

As shown in FIG. 12, the stacked film FL1 is divided into a plurality of portions by the partition 6B. In this embodiment, as shown in FIG. 6, the partition 6B includes a plurality of segments SG, and each segment SG has a plurality of apertures APa, APb and APc. In this configuration, as the stacked film FL1 is divided into pieces in the areas where the partition 6B is divided, the effect of preventing the removal of the stacked film FL1 is enhanced.

In the example of FIG. 12, the stacked film FL1 is divided by the overhang structure OH1. As the stacked film FL1 is divided in the area between the segments SG in this manner, the effect of preventing the removal of the stacked film FL1 is further improved.

Similarly, the overhang structures OH1 formed along the slit SLb shown in FIG. 4 and the slit SLc shown in FIG. 5 divide the stacked film FL1. It is difficult to form the base layers of the partitions 6A and 6B and resists for pattering these layers so as to have stable thicknesses in the peripheral portion of the mother substrate MB shown in FIG. 4. Therefore, the partition 6B cannot be formed in the peripheral portion of the mother substrate MB. Even in this case, when the slit SLb which surrounds the panel portions PP is provided, the stacked film FL1 can be divided in the peripheral portion of the mother substrate MB.

In the example of FIG. 13, the stacked film FL1 is divided by the overhang structure OH2. By this configuration, the stacked film FL1 can be divided along the outer shape of the inspection pad PD.

In the example of FIG. 14, the stacked film FL1 is divided by the overhang structure OH3. In this manner, the stacked film FL1 can be divided by the overhang structure OH3 using the rib layer 5 and the inorganic insulating layer 32 in a portion where the organic insulating layer 12 or 33 is not provided, such as the vicinity of the cut line CL1.

In the examples of FIG. 12 to FIG. 14, the stacked film FL1 is divided. It should be noted that the stacked films FL2 and FL3 are similarly divided by the partition 6B and the overhang structures OH1, OH2 and OH3.

If a conductive body having a large area is formed by the partition 6B and the upper electrodes UE1, UE2 and UE3 in the surrounding area SA, the inspection area TA and the margin area BA, electrostatic discharge (ESD) is easily caused by the conductive body. If electrostatic discharge is caused, the surrounding elements may be damaged.

In this respect, in the embodiment, the partition 6B is divided into the segments SG, and further, the stacked films FL1, FL2 and FL3 (the upper electrodes UE1, UE2 and UE3) are divided by the overhang structures OH1, OH2 and OH3. This configuration can prevent the formation of a conductive body having a large area in the surrounding area SA, the inspection area TA and the margin area BA in the manufacturing process of the display device DSP.

The configuration of the embodiment can prevent the removal of the stacked films FL1, FL2 and FL3 and electrostatic discharge and improve the yield at the time of manufacturing the display device DSP and the mother substrate MB.

### Second Embodiment

FIG. 15 is a schematic plan view showing the configuration of a mother substrate MB or a display device DSP according to a second embodiment. This plan view shows segments SG (partition 6B) provided in a margin area BA, a surrounding area SA and an inspection area TA in a manner similar to that of FIG. 6.

The shapes and layout form of the segments SG shown in FIG. 15 are the same as the example of FIG. 6. However, in the example of FIG. 15, an intersection portion 50 formed of a rib layer 5 is provided at each intersection of a slit SLa having a grating shape. The rib layer 5 has a plurality of parts 51 which are divided by the slit SLa having the grating shape. The segments SG are provided on the respective parts 51. The intersection portions 50 are spaced apart from the parts 51.

In the example of FIG. 15, each intersection portion 50 is a square. However, each intersection portion 50 may have another shape such as a rectangle, a circle or an oval. The intersection portions 50 are not necessarily provided at all of the intersections of the slit SLa.

FIG. 16 is the schematic cross-sectional view of the mother substrate MB along the XVI-XVI line of FIG. 15. As described above, an organic insulating layer 12 has a groove 12a which overlaps the slit SLa. For example, the edge portion E50 of the intersection portion 50 has a taper shape in which the thickness decreases toward the distal end. Further, the edge portion E50 protrudes above the groove 12a. In other words, an overhang structure OH4 along the outer shape of the intersection portion 50 is formed by the edge portion E50 and the groove 12a. For example, the overhang structure OH4 is formed in the whole outer periphery of the intersection portion 50.

FIG. 17 is a schematic cross-sectional view showing the effect of this embodiment and shows the state in which a stacked film FL1 is formed in the intersection portion 50 shown in FIG. 16 and the surrounding area. In a manner similar to that of the overhang structure OH1 shown in FIG. 12, the stacked film FL1 is divided by the overhang structure OH4. Similarly, the stacked films FL2 and FL3 are divided by the overhang structures OH4.

In the first embodiment, the slit SLa which surrounds the segments SG has a continuous grating shape (see FIG. 6). In this case, the stacked films FL1, FL2 and FL3 which are formed at the time of manufacturing the display device DSP have grating shapes similar to the grating shape of the slit SLa. Thus, if the removal of the stacked films FL1, FL2 and FL3 is caused in the slit SLa, the range of the removal easily expands in the slit SLa. In addition, the areas of upper electrodes UE1, UE2 and UE3 included in the stacked films FL1, FL2 and FL3 are also increased. Thus, the possibility of electrostatic discharge is increased.

However, in this embodiment, the stacked films FL1, FL2 and FL3 formed in the slit SLa are divided by the intersection portions 50. By this configuration, the removal of the stacked films FL1, FL2 and FL3 in the slit SLa can be prevented. Moreover, since the upper electrodes UE1, UE2 and UE3 having large areas are not easily formed in the slit SLa, the electrostatic discharge in the vicinity of the slit SLa can be also prevented.

All of the display devices, mother substrates and manufacturing methods that can be implemented by a person of ordinary skill in the art through arbitrary design changes to the display device, mother substrate and manufacturing method disclosed in each of the embodiments described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate having a display area which displays an image and a surrounding area around the display area;
an organic insulating layer formed of an organic insulating material and provided above the substrate;
a lower electrode provided above the organic insulating layer in the display area;
a rib layer which is formed of an inorganic insulating material, covers the organic insulating layer and the lower electrode and has a pixel aperture overlapping the lower electrode;
a first partition provided above the rib layer in the display area;
an organic layer which is in contact with the lower electrode through the pixel aperture and emits light based on application of voltage;
an upper electrode which covers the organic layer and is in contact with the first partition; and
a second partition provided above the rib layer in the surrounding area, wherein
each of the first partition and the second partition includes a lower portion provided above the rib layer and an upper portion having an end portion which protrudes from a side surface of the lower portion,
the second partition includes a plurality of segments which are spaced apart from each other, and
the rib layer has a slit which surrounds at least one of the segments.

2. The display device of claim 1, wherein
the organic insulating layer has a groove which overlaps the slit.

3. The display device of claim 2, wherein
a first overhang structure, in which an edge portion of the rib layer protrudes above the groove, is formed along the slit.

4. The display device of claim 3, wherein
the organic layer and the upper electrode are provided in the surrounding area, and
the organic layer and the upper electrode provided in the surrounding area are divided by the first overhang structure.

5. The display device of claim 1, wherein
each of the segments has a plurality of apertures.

6. The display device of claim 1, wherein
the slit has a grating shape including a plurality of intersections, and
the rib layer has an intersection portion provided at at least one of the intersections.

7. The display device of claim 6, wherein
the rib layer has a plurality of parts which are divided by the slit having the grating shape, and
the intersection portion of the rib layer is spaced apart from the plurality of parts.

8. The display device of claim 6, wherein
the organic insulating layer has a groove which overlaps the slit,
the intersection portion of the rib layer is formed into an island-like shape as seen in plan view, and
a second overhang structure, in which an edge portion of the intersection portion protrudes above the groove, is formed in an outer periphery of the intersection portion.

9. The display device of claim 8, wherein
the second overhang structure is formed in a whole outer periphery of the intersection portion of the rib layer.

10. The display device of claim 8, wherein
the organic layer and the upper electrode are provided in the surrounding area, and
the organic layer and the upper electrode provided in the surrounding area are divided by the second overhang structure.

11. A mother substrate for a display device, the mother substrate comprising:
a substrate which has a plurality of panel portions each including a display area and a surrounding area around the display area, and a margin area around the panel portions;
an organic insulating layer formed of an organic insulating material and provided above the substrate;
a lower electrode provided above the organic insulating layer in the display area;
a rib layer which is formed of an inorganic insulating material, covers the organic insulating layer and the lower electrode and has a pixel aperture which overlaps the lower electrode;
a first partition provided above the rib layer in the display area;
an organic layer which is in contact with the lower electrode through the pixel aperture and emits light based on application of voltage;
an upper electrode which covers the organic layer and is in contact with the first partition; and
a second partition provided above the rib layer in at least one of the surrounding area and the margin area, wherein
each of the first partition and the second partition includes a lower portion provided above the rib layer and an upper portion having an end portion protruding from a side surface of the lower portion,
the second partition includes a plurality of segments which are spaced apart from each other, and
the rib layer has a slit which surrounds at least one of the segments.

12. The mother substrate of claim 11, wherein
the organic insulating layer has a groove which overlaps the slit.

13. The mother substrate of claim 12, wherein
a first overhang structure, in which an edge portion of the rib layer protrudes above the groove, is formed along the slit.

14. The mother substrate of claim 13, wherein
the organic layer and the upper electrode are provided in the surrounding area, and
the organic layer and the upper electrode provided in the surrounding area are divided by the first overhang structure.

15. The mother substrate of claim 11, wherein
each of the segments has a plurality of apertures.

16. The mother substrate of claim 11, wherein
the slit has a grating shape including a plurality of intersections, and
the rib layer has an intersection portion provided at at least one of the intersections.

17. The mother substrate of claim 16, wherein
the rib layer has a plurality of parts which are divided by the slit having the grating shape, and
the intersection portion of the rib layer is spaced apart from the plurality of parts.

18. The mother substrate of claim 16, wherein
the organic insulating layer has a groove which overlaps the slit,
the intersection portion of the rib layer is formed into an island-like shape as seen in plan view, and
a second overhang structure, in which an edge portion of the intersection portion protrudes above the groove, is formed in an outer periphery of the intersection portion.

19. The mother substrate of claim 18, wherein
the second overhang structure is formed in a whole outer periphery of the intersection portion of the rib layer.

20. The mother substrate of claim 18, wherein
the organic layer and the upper electrode are provided in the surrounding area, and
the organic layer and the upper electrode provided in the surrounding area are divided by the second overhang structure.
